(19) United States
(12) Patent Application Publication
(10) Pub. No.: US 2021/0257231 A1
(43) Pub. Date: Aug. 19, 2021

(54) SEMICONDUCTOR MANUFACTURING APPARATUS AND METHOD FOR MANUFACTURING SEMICONDUCTOR DEVICE

(71) Applicant: POWERTECH TECHNOLOGY INC., Hsinchu County (TW)

(72) Inventor: Shinichi Sakurada, HSINCHU COUNTY (TW)

(21) Appl. No.: 16/920,409

(22) Filed: Jul. 2, 2020

(30) Foreign Application Priority Data
Feb. 17, 2020 (JP) 2020-023906

(51) Int. Cl. H01L 21/67; H01L 21/683

(52) U.S. Cl. CPC H01L 21/67132; H01L 21/6836

(57) ABSTRACT

A semiconductor manufacturing apparatus includes a supporting stage for mounting a semiconductor wafer with a protective member attached thereto, a pressing device for pressing the semiconductor wafer with a protective member attached thereto, an ultraviolet irradiation device, and a chamber for housing the supporting stage, the pressing device, and the ultraviolet irradiation device. The pressing device includes an ultraviolet transmitting plate. The pressing device drives the ultraviolet transmitting plate to generate a pressing force for pressing the semiconductor wafer with a protective member attached thereto on a supporting stage. The pressing device is moved relatively to the supporting stage such that the semiconductor wafer and the protective member are sandwiched between the ultraviolet transmitting plate and the supporting stage. The ultraviolet rays emitted from the ultraviolet irradiation device pass through the ultraviolet transmitting plate and are irradiated to the protective member.

### BACKGROUND OF THE INVENTION

### 1. Field of the Invention

The present disclosure relates to a semiconductor manufacturing apparatus and a manufacturing method thereof, more particularly to a semiconductor manufacturing apparatus for manufacturing a thin semiconductor element and a manufacturing method thereof.

### 2. Description of the Prior Art

In recent years, with the miniaturization and high density of electronic devices, electronic components such as semiconductor wafers have been required to become thinner. Thus, the demands for thinning the semiconductor wafers to tens of micrometers in thickness are increased. Besides, in order to improve yields, the diameter of the semiconductor wafers also becomes greater.

Generally, for the semiconductor wafers manufactured in a large-diameter state, the electrodes are formed on the surface of the semiconductor wafer by photolithography, etching or sputtering based on specific circuit patterns through photoresist coating, etching, ion implantation, and polishing. After the electrodes are formed on the surface of the semiconductor wafer, a grinding process (which is called as rear surface grinding process hereinafter) is performed on the rear surface of the semiconductor wafer in order to achieve a specific thickness. In addition, a rear processing (such as etching or polishing), a cutting processing, and etc. may be performed if needed.

At this time, for the purpose of such as protecting the circuit pattern of the semiconductor wafer, the rear surface grinding process is performed on the rear surface of the semiconductor wafer after a laminating process is performed on the surface of the semiconductor wafer by a protective tape. In addition, after the semiconductor wafer is cut to have a specific thickness through a half cutting process (forming a recess), the laminating process and the rear surface grinding process may be performed during a dicing before grinding (DBG) process.

Generally, the protective tape used in the manufacturing process is composed of a base material and an adhesive layer formed on the base material. In general, when laminating the protective tape onto the surface of the semiconductor wafer, an laminating apparatus is used to load the semiconductor wafer on the laminating stage with its surface (surface having circuits) faced upward to adhere the adhesive layer of the protective tape to the surface of the semiconductor wafer from above by pressing means such as pressing rolls, in which the pressure is applied in sequence along the adhering direction, such that the protective tape is closely attached to the surface of the semiconductor wafer.

After that, the semiconductor wafer is loaded on a chuck stage, and the rear surface grinding process is performed. At this time, the semiconductor wafer is loaded on the chuck stage with its rear surface (the surface not having the protective tape attached thereon) facing upward and being exposed and the surface of the semiconductor wafer (the surface having the protective tape attached thereon) facing downward to the flat surface of the chuck stage. In the meanwhile, the semiconductor wafer is vacuum adsorbed on the chuck stage through the protective tape, and the rear surface of the semiconductor wafer is grinded to have specific thickness simultaneously.

However, thickness variation may exist in the adhesive layer of the conventional protective tape, and the thickness variation may cause partial uplift of the base material, such that the surface of the protective tape may be uneven. With different materials of the adhesive, the total thickness variation (TTV) of the surface of the protective tape may generally range from 2 micrometers to 6 micrometers. Therefore, when the semiconductor wafer is vacuum adsorbed on the chuck stage through the protective tape, the thickness variation of the protective tape may be transferred to the semiconductor wafer, such that the surface flatness of the semiconductor wafer is reduced, thereby causing the problems of low quality such as uneven thickness (for example, the package is wrapped due to thickness variation) of the semiconductor wafer after the rear surface grinding process.

Furthermore, for a product (such as a multi-chip package) having a plurality of semiconductor chips stacked in multiple stages on the substrate thereof, when the thickness variation of each of the semiconductor chips is greater, the height variation of the entire semiconductor chips may be greater, which will adversely affect the subsequent wire bonding step or packaging step.

In order to solve the above-mentioned problems, a cutting process is performed on the protective tape by a cutting device, such that the surface of the tape may become flat in the conventional technology. However, when the protective tape is cut by the cutting device, scraps of the protective tape with string shape may be generated, and when the protective tape with remained scraps is adhered to the semiconductor wafer, the grinding thickness of the semiconductor wafer may be affected in the subsequent grinding process to the semiconductor wafer. Moreover, the scraps of the protective tape may also adhere to the rear surface of the semiconductor wafer, and the scraps may be difficult to remove even if the semiconductor wafer is washed and cleaned.

### SUMMARY OF THE INVENTION

According to the above-mentioned problems in the prior art, the purpose of the present invention is to provide a semiconductor manufacturing apparatus and a semiconductor manufacturing method to prevent the thickness accuracy of the semiconductor wafer from reducing by eliminating the thickness variation of the protective tape, thereby improving the quality of the semiconductor chip after dicing.

According to an embodiment of the present disclosure, a semiconductor manufacturing apparatus includes: a supporting stage for mounting a semiconductor wafer, wherein a protective member is attached to the semiconductor wafer; a pressing device disposed opposite to the supporting stage for pressing the semiconductor wafer with the protective member attached thereto; an ultraviolet irradiation device for irradiating the protective member with an ultraviolet ray; and a chamber for housing the supporting stage, the pressing device and the ultraviolet irradiation device, wherein the pressing device comprises an ultraviolet transmitting plate, the pressing device drives the ultraviolet transmitting plate to generate a pressing force for pressing the semiconductor wafer with a protective member attached thereto on the supporting stage, the ultraviolet transmitting plate is disposed at a side of the pressing device facing the supporting stage and withstands the pressing force from the pressing device, the pressing device is moved relatively to the supporting stage to make the ultraviolet transmitting plate in contact with a surface of the protective member that is opposite to the attaching surface of the protective member and the semiconductor wafer, such that the semiconductor wafer with the protective member attached thereto is sandwiched between the ultraviolet transmitting plate and the supporting stage, and the ultraviolet ray emitted from the ultraviolet irradiation device passes through the ultraviolet transmitting plate and is irradiated to the protective member.

According to another embodiment of the present disclosure, a semiconductor manufacturing method includes: a preparing step for preparing a semiconductor wafer having a first main surface and a second main surface and a protective member having a first main surface and a second main surface; a laminating step for attaching the first main surface of the semiconductor wafer to the first main surface of the protective member; a pressing step for pressing the protective member attached to the semiconductor wafer regarding the second main surface of the protective member as the pressing surface; and a hardening step for hardening the protective member attached to the semiconductor wafer by irradiating an ultraviolet ray under the condition that the second main surface of the protective member is being pressed, wherein a thickness of the protective member is substantially uniform by the pressing step, and the substantially uniform thickness of the protective member is maintained by the hardening step.

According to another embodiment of the present disclosure, a method for manufacturing a semiconductor device includes preparing a semiconductor wafer including a first surface, a second surface opposite to the first surface, and a plurality of semiconductor chips formed on the first surface, preparing a protective member including an adhesive layer that is ultraviolet curable, laminating the protective member on the first surface of the semiconductor wafer so that the adhesive layer faces the semiconductor wafer, pressing the semiconductor wafer via the protective member by a pressing plate, the pressing plate having permeability for an ultraviolet ray, and irradiating the ultraviolet ray to the adhesive layer of the protective member while keeping the semiconductor wafer via the protective member being pressed by the pressing plate for curing the adhesive layer, wherein the pressing the semiconductor wafer and the irradiating the ultraviolet ray are performed in a chamber.

According to the semiconductor manufacturing apparatus and the semiconductor manufacturing method of the present disclosure, under the condition that the protective member is attached on the surface of the semiconductor wafer, the thickness of the protective member may substantially be uniform by flattening the adhesive layer of the protective member, thereby reducing the condition of uneven thickness of the semiconductor wafer.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 schematically illustrates a lateral cross-sectional view of a semiconductor manufacturing apparatus according to an embodiment of the present disclosure.

FIG. 2 schematically illustrates an enlarged cross-sectional view corresponding to a dotted-line portion in FIG. 1.

FIG. 3 schematically illustrates a lateral cross-sectional view of a semiconductor manufacturing apparatus according to an embodiment of the present disclosure.

FIG. 4 schematically illustrates an enlarged cross-sectional view corresponding to a dotted-line portion in FIG. 3.

FIG. 5 schematically illustrates a top view of a semiconductor manufacturing apparatus according to another embodiment of the present disclosure.

FIG. 6 schematically illustrates a semiconductor manufacturing apparatus according to another embodiment of the present disclosure.

FIG. 7 schematically illustrates a top view of a semiconductor manufacturing apparatus according to another embodiment of the present disclosure.

FIG. 8 schematically illustrates a semiconductor manufacturing apparatus according to another embodiment of the present disclosure.

FIG. 9 schematically illustrates a flow chart of a semiconductor manufacturing method according to another embodiment of the present disclosure.

### DETAILED DESCRIPTION

The present invention may be understood by reference to the following detailed description, taken in conjunction with the drawings as described below. The present invention is not limited to the contents described in the following embodiments. The constituent elements of the present invention described below may refer to the constituent elements substantially the same or readily observed by one skilled in the art. In addition, the constituent elements described below can be appropriately combined with each other and may be omitted, replaced, or modified in many different ways, without departing from the scope of the present invention.

### Embodiment 1

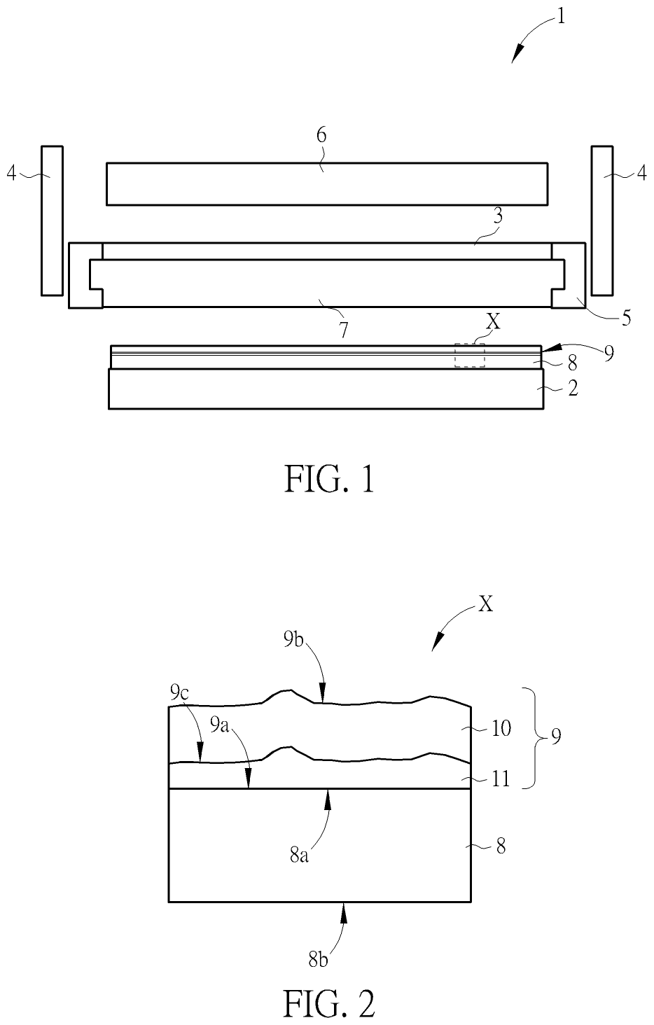

FIG. 1 schematically illustrates a semiconductor manufacturing apparatus 1 according to embodiment 1 of the present disclosure. The semiconductor manufacturing apparatus 1 includes a supporting stage 2, wherein a semiconductor wafer 8 is on the supporting stage 2 and a protective member 9 is attached to the semiconductor wafer 8; a pressing device 3 disposed opposite to the supporting stage 2; an ultraviolet irradiation device 6 for hardening (or curing) the adhesive layer 11 (as shown in FIG. 2) of the protective member 9; and a chamber 4 for housing the supporting stage 2, the pressing device 3 and the ultraviolet irradiation device 6.

The semiconductor wafer 8 is mounted on the supporting stage 2. A laminating process performed on the surface of the semiconductor wafer 8 has been finished by a laminating device (not shown). The protective member 9 is attached to the surface of the semiconductor wafer 8 through an adhesive layer 11.

The pressing device 3 may also include a plate 7. The pressing device 3 may be configured to be freely lift (or elevate) and lower through a lifting device (not shown). A pressing force may be generated by driving the plate 7 through lifting or lowering the pressing device 3 to press the semiconductor wafer 8 with the protective member 9 attached thereto on the supporting stage 2.

The plate 7 (or pressing plate) is disposed at a side of the pressing device 3 facing the supporting stage 2 and bears the pressing force from the pressing device 3. In an embodiment of the present disclosure, the plate 7 is an ultraviolet transmitting plate, but not limited thereto.

FIG. 2 is an enlarged view corresponding to a dotted-line portion in FIG. 1, which shows the cross-sectional view of the protective member 9 and the semiconductor wafer 8 before pressing. The protective member 9 is a stacked structure of two or more layers in which the base material 10 and the adhesive layer 11 are the main body. After the above-mentioned laminating process, the adhesive layer 11 faces the semiconductor wafer 8. The protective member 9 includes a first main surface 9a attached to a first main surface 8a of the semiconductor wafer 8, a second main surface 9b opposite to the first main surface 9a and bearing the pressing from the plate 7, and a third main surface 9c which is the attaching surface of the base material 10 and the adhesive layer 11. In the present embodiment, a plurality of semiconductor chips may be formed on the first main surface 8a of the semiconductor wafer 8, but not limited thereto. As shown in FIG. 2, the thickness of the adhesive layer 11 varies, and affected by this, the third main surface 9c where the adhesive layer 11 is attached to the base material 10 is uneven. Besides, the uneven third main surface 9c will cause partial uplift of the base material 10, such that the second main surface 9b of the protective member 9 may also become uneven.

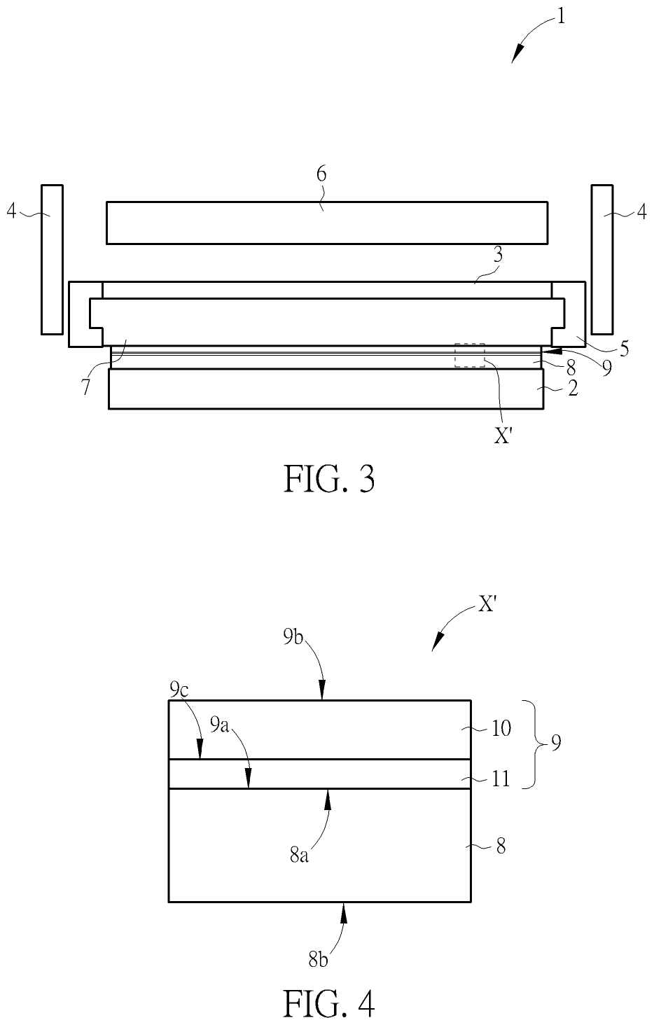

After that, as shown in FIG. 3 and FIG. 4, the pressing device 3 is moved relatively to the supporting stage 2 through the lifting device (not shown), such that the second main surface 9b of the protective member 9 may be in contact with the plate 7, and the semiconductor wafer 8 with the protective member 9 attached thereto may be sandwiched between the plate 7 and the supporting stage 2. An ultraviolet ray emitted from the ultraviolet irradiation device 6 may pass through the plate 7 and be irradiated to the protective member 9, such that the adhesive layer 11 of the protective member 9 may be hardened.

FIG. 4 is an enlarged view corresponding to a dotted-line portion X′ in FIG. 3, which shows the cross-sectional view of the protective member 9 and the semiconductor wafer 8 after pressing. The uneven situations of the third main surface 9c where the base material 10 is attached to the adhesive layer 11 and the second main surface 9b of the protective member 9 may be rectified or corrected by pressing, such that the third main surface 9c and the second main surface 9b may become flat. In addition, the adhesive layer 11 of the protective member 9 is hardened by being irradiated with ultraviolet ray while it is corrected by pressing, such that the third main surface 9c and the second main surface 9b may maintain in a flat state.

In the present embodiment, the protective member 9 is hardened after the pressing step, but the order of these processes is not limited thereto. For example, the pressing step and the hardening step may be performed at the same time.

Besides, in the present embodiment, the protective member 9 is irradiated with the ultraviolet ray in the chamber 4, thus no ultraviolet ray will leak around the pressing device 3, and the situation that the protective member 9 and the semiconductor wafer 8 yet to be pressed and treated are irradiated with the ultraviolet ray can be prevented.

In the present embodiment, the pressing device 3 can be moved relatively to the supporting stage 2 by lifting or lowering the pressing device 3. However, the supporting stage 2 may also be moved relatively to the pressing device 3 by lifting or lowering the supporting stage 2, or both of the pressing device 3 and the supporting stage 2 may be moved relatively to each other by lifting or lowering of the supporting stage 2 and the pressing device 3.

The protective member 9 may for example include tape, thin film or flakes. In detail, the tape is used in the embodiments of the present disclosure.

In addition, because the adhesive layer 11 of the protective member 9 includes the adhesive material which can be hardened by ultraviolet ray in the present embodiment, the hardening may be performed by irradiating ultraviolet ray. However, other hardening methods are also available. For example, according to the hardening type of the adhesive material of the adhesive layer 11 of the protective member 9, the adhesive layer 11 of the protective member 9 may be hardened by being irradiated with radiation, heating or the combination of the above-mentioned methods.

The irradiation method is not limited to the ultraviolet ray. If the adhesive layer whose characteristics are changed due to irradiation with specific light or heating is used, the corresponding specific light or the heating method can be used.

The heating method may include heating gas or thermal rays.

The adhesive layer 11 may for example include thermosetting or photocuring adhesive materials which are known in the technical field of semiconductor device manufacturing.

In the present embodiment, the adhesive layer 11 of the protective member 9 is hardened by using ultraviolet ray. Therefore, the material of the adhesive layer 11 includes the characteristic of being hardened by the ultraviolet ray, and the material of the base material 10 may include the characteristic of ultraviolet ray transmitting.

The plate 7 may include materials with rigidity and high surface accuracy such as glass plate, steel plate or plates formed of resin. Besides, the material of the plate 7 may be a material having excellent radiation transmission under the condition that a radiation irradiation method is adopted for hardening the adhesive layer 11 of the protective member 9.

In the present embodiment, the plate 7 is the glass plate having ultraviolet transmitting property. However, the material of the plate 7 is not limited to glass provided that the flatness and hardness of the surface of the plate 7 can be ensured which is used for pressing the protective member 9 and the plate 7 has ultraviolet transmitting property. As long as the above-mentioned conditions are satisfied, the plate 7 may also be formed of resin material. Furthermore, in order to suppress the temperature rise caused by the irradiation conditions of ultraviolet irradiation, the plate 7 can also be used in addition with an ultraviolet diffusion filter.

In the present embodiment, in order to prevent the non-laminated protective member 9 in the semiconductor manufacturing apparatus 1 from being affected by the ultraviolet ray, or to prevent the semiconductor wafer 8 and the protective member 9, yet to be pressing treated, in the wafer loader, alignment portion or other devices of the semiconductor manufacturing apparatus 1 from being affected by the ultraviolet ray, the pressing step and the hardening step may be performed in the chamber 4.

The chamber 4 at least houses or contains the pressing device 3 and the ultraviolet irradiation device 6. Furthermore, the chamber may also house the supporting stage, the wafer loader, the transporting portion, the alignment portion, the laminating portion and the wafer unloader.

In the present embodiment, the outer sidewall of the chamber 4 has ultraviolet-blocking property. In the case that the adhesive layer 11 of the protective member 9 is hardened by using other radiation irradiation method, the outer sidewall of the chamber 4 may have the blocking property against the corresponding radiation. Besides, in the case that the adhesive layer 11 of the protective member 9 is hardened by heating, an adiabatic chamber 4 can be used.

The pressing device 3 may simultaneously press the whole area of the surface (that is, the second main surface 9b) which is opposite to the attaching surface (the first main surface 9a) of the protective member 9 and the semiconductor wafer 8. In addition, the area on which the simultaneously pressing is performed may be greater than or equal to the area of the first main surface 9a of the protective member 9.

The area being irradiated with the ultraviolet ray may be greater than or equal to the area of the attaching surface (the first main surface 9a) of the protective member 9 and the semiconductor wafer 8. The irradiation amount of the ultraviolet ray can be appropriately determined according to the material of the adhesive layer 11.

The semiconductor manufacturing apparatus 1 of the present disclosure may further include a connecting fixture 5. In the present embodiment, the connecting fixture 5 is connected to the pressing device 3 and the plate 7, and is interlocked with the lifting and lowering motion of the pressing device 3.

The pressing device 3 and the ultraviolet irradiation device 6 may be configured in an in-line way or in a standalone way. The in-line configuration is to systemize the pressing device 3 and the ultraviolet irradiation device 6 with the rear surface grinding portion, the alignment portion, the laminating portion, the cleaning portion, and etc. to become a series of processes. Besides, the standalone configuration is to separate the pressing device 3 and the ultraviolet irradiation device 6 from other devices, wherein the pressing device 3 and the ultraviolet irradiation device 6 are disposed separately.

The thickness of the protective member 9 may substantially be uniform by pressing of the pressing device 3. In addition, the substantially uniform thickness of the protective member 9 may be maintained by the ultraviolet irradiation device 6. In detail, the thickness of the protective member 9 being substantially uniform means that the total thickness variation (TTV) of the protective member 9 may be less than or equal to 1 micrometer.

### Example 1

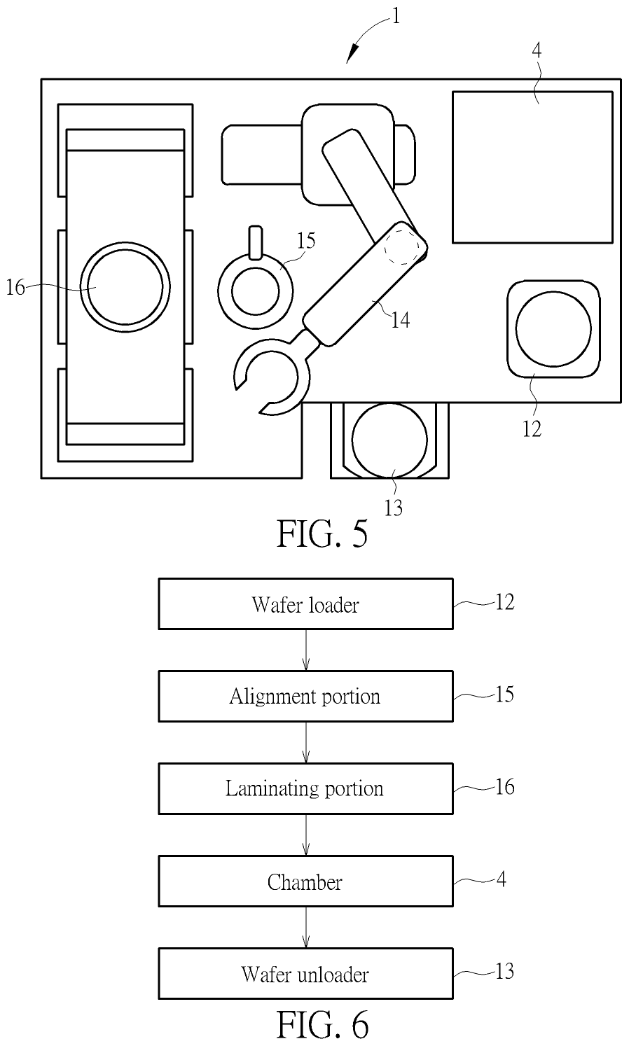

As shown in FIG. 5, the semiconductor manufacturing apparatus 1 of the present disclosure may include a chamber 4, and the chamber 4 houses the ultraviolet irradiation device (not shown), the pressing device (not shown), the supporting stage (not shown), and the ultraviolet transmitting plate (not shown) mentioned above. Besides, the semiconductor manufacturing apparatus 1 of the present embodiment may further include the wafer loader 12, the wafer unloader 13, the transporting portion 14, the alignment portion 15 and the laminating portion 16. In the present embodiment, the pressing device and the ultraviolet irradiation device are configured in an in-line way in the laminating device.

In the following, FIG. 5 and FIG. 6 are used to schematically illustrate the semiconductor manufacturing apparatus of example 1 of the present embodiment. First, a carrier case housing a plurality of semiconductor wafers (not shown) is disposed in the wafer loader 12. After that, the semiconductor wafers are transported from the wafer loader 12 to the alignment portion 15 by the transporting device of the transporting portion 14 to perform an alignment step. Then, the semiconductor wafers are transported from the alignment portion 15 to the laminating portion 16 by the transporting device of the transporting portion 14 to perform the laminating step for attaching the protective member (not shown) to the semiconductor wafer (not shown). In the laminating step, after the protective member is attached to the semiconductor wafer, the protective member is cut according to the size of the semiconductor wafer and is laminated on the semiconductor wafer. After that, the semiconductor wafers with the protective member attached thereto are transported from the laminating portion 16 to the chamber 4 by the transporting device of the transporting portion 14. The chamber 4 houses the supporting stage (not shown), the pressing device (not shown), the ultraviolet irradiation device (not shown), and the ultraviolet transmitting plate (not shown). After the semiconductor wafers with the protective member attached thereto are transported into the chamber 4, they are mounted on the supporting stage. Then, the semiconductor wafers with the protective member attached thereto are pressed by the pressing device, such that the adhesive layer of the protective member may become flat. In such condition, the ultraviolet ray emitted from the ultraviolet irradiation device may pass through the ultraviolet transmitting plate, and the adhesive layer of the protective member may be irradiated with the ultraviolet ray in order to harden the flattened adhesive layer. After that, the processed semiconductor wafers are transported from the chamber 4 to the wafer unloader 13 by the transporting device of the transporting portion 14. In the wafer unloader 13, the semiconductor wafers after laminating process are housed in a wafer cassette case (not shown).

In addition, in the present example, the case applied to the laminating device is described. However, the pressing device and the ultraviolet irradiation device may further apply to the rear surface grinding device of the semiconductor wafer to flatten the adhesive layer of the protective member before the step of rear surface grinding of the semiconductor wafer with the protective member attached thereto.

### Example 2

In the semiconductor manufacturing apparatus of the present embodiment, the pressing device and the ultraviolet irradiation device are configured in a standalone way. The standalone configuration may be described by the example 2 in the following contents, and the same parts of example 2 and example 1 will not be redundantly described.

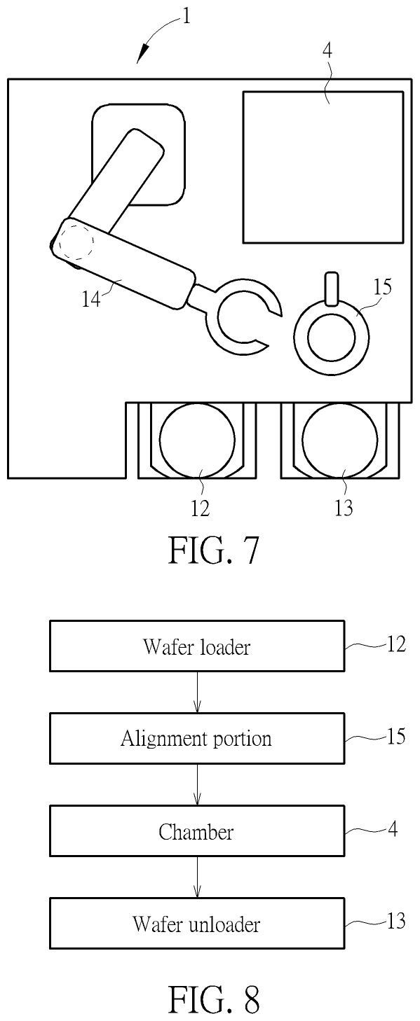

In the following, FIG. 7 and FIG. 8 are used to schematically illustrate the semiconductor manufacturing apparatus of example 2 of the present disclosure. First, the wafer cassette case (not shown) is disposed in the wafer loader 12, wherein the wafer cassette case houses the semiconductor wafers (not shown) with the protective member (not shown) attached thereto produced after the laminating step is finished. After that, the semiconductor wafers are transported from the wafer loader 12 to the alignment portion 15 by the transporting device of the transporting portion 14 to perform the alignment step. Then, the semiconductor wafers after alignment are transported from the alignment portion 15 to the chamber 4 by the transporting device of the transporting portion 14. The chamber 4 houses the supporting stage (not shown), the pressing device (not shown), the ultraviolet irradiation device (not shown), and the ultraviolet transmitting plate (not shown). After the semiconductor wafers with the protective member attached thereto are transported into the chamber 4, they are mounted on the supporting stage. Then, the semiconductor wafers with the protective member attached thereto are pressed by the pressing device, such that the adhesive layer of the protective member becomes flat. In such condition, the ultraviolet ray emitted from the ultraviolet irradiation device may pass through the ultraviolet transmitting plate to irradiate the adhesive layer of the protective member so as to harden the flattened adhesive layer. After that, the processed semiconductor wafers are transported from the chamber 4 to the wafer unloader 13 by the transporting device of the transporting portion 14. In the wafer unloader 13, the semiconductor wafers after the pressing step are housed in a wafer cassette case (not shown).

In example 1 and example 2, the wafer loader 12 and the wafer unloader 13 are disposed separately, but they may be integrated into a single wafer loader/unloader in variant examples.

### Embodiment 2

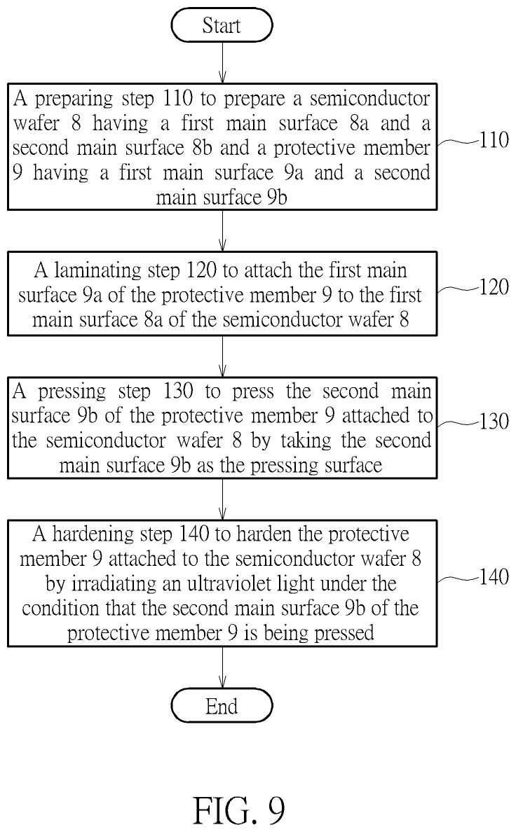

In the following, FIG. 9 is used to schematically illustrate the processes of the semiconductor manufacturing method 100 of the present disclosure. The semiconductor manufacturing method 100 includes a preparing step 110 to prepare a semiconductor wafer 8 having a first main surface 8a and a second main surface 8b and a protective member 9 having a first main surface 9a and a second main surface 9b, a laminating step 120 to attach the first main surface 8a of the semiconductor wafer 8 to the first main surface 9a of the protective member 9, a pressing step 130 to press the second main surface 9b of the protective member 9 attached to the semiconductor wafer 8 by taking the second main surface 9b as the pressing surface, and a hardening step 140 to harden the protective member 9 attached to the semiconductor wafer 8 by irradiating an ultraviolet ray under the condition that the second main surface 9b of the protective member 9 is being pressed.

The thickness of the adhesive layer 11 of the protective member 9 may become substantially uniform by the pressing step 130, and the substantially uniform thickness of the adhesive layer 11 of the protective member 9 may be maintained by the hardening step 140. In detail, the substantially uniform thickness means that the total thickness variation of the protective member 9 may be less than or equal to 1 micrometer.

In the pressing step 130, the pressing device of the semiconductor manufacturing apparatus of the present disclosure may simultaneously press the whole area of the second main surface 9b of the protective member 9.

In the present embodiment, in the hardening step 140 of hardening the adhesive layer 11 of the protective member 9, because the adhesive layer 11 of the protective member 9 includes the adhesive material which can be hardened by ultraviolet ray, the hardening may be performed by irradiating ultraviolet ray. However, other hardening methods are also available according to the hardening type of the adhesive layer 11. For example, the adhesive layer 11 of the protective member 9 may be hardened by being irradiated with radiation, heating or the combination of the above-mentioned methods.

The irradiation method is not limited to the ultraviolet ray. If the adhesive layer whose characteristics are changed due to irradiation with specific light or heating, the corresponding specific light or the heating method can be adopted. The use of ultraviolet ray is suggested.

The heating method may include heating gas or thermal rays.

In the present embodiment, the hardening step is performed after the pressing step on the protective member 9. However, the order of these steps is not limited thereto. For example, the pressing step and the hardening step may be performed simultaneously.

The semiconductor manufacturing method of the present disclosure may further include a rear surface grinding step, an alignment step, a peeling step or a cleaning step. For example, the second main surface 8b of the semiconductor wafer may be grinded while the protective member 9 is laminated on the semiconductor wafer 8 after the irradiating irradiation of the ultraviolet ray, but not limited thereto.

In addition, in the present disclosure, the step of pressing the protective member 9 attached to the semiconductor wafer 8, the step of irradiating with ultraviolet ray, and the step of hardening the flattened adhesive layer 11 of the protective member 9 may be performed in any stage after the laminating step of the semiconductor wafer 8 and the protective member 9 and before the rear surface grinding step of the semiconductor wafer 8.

The pressing step 130 and the hardening step 140 may be performed in an in-line way or in a standalone way. In the in-line way, the pressing step 130 and the hardening step 140 are systemized with the rear surface grinding step, the alignment step, the peeling step or the cleaning step to become a series of processes. Besides, in the standalone way, the pressing step 130 and the hardening step 140 are separated from other steps, and are performed separately.

As mentioned above, the semiconductor manufacturing apparatus and the semiconductor manufacturing method of the present disclosure may be used to manufacture semiconductor elements. In particular, the thickness of the protective member may be substantially uniform by eliminating the unevenness of the adhesive layer of the protective member to flatten the surface of the adhesive layer, thereby reducing the condition of uneven thickness of the semiconductor wafer.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor manufacturing apparatus, comprising:
a supporting stage for mounting a semiconductor wafer, wherein a protective member is attached to the semiconductor wafer;
a pressing device disposed opposite to the supporting stage for pressing the semiconductor wafer with the protective member attached thereto;
an ultraviolet irradiation device for irradiating the protective member with an ultraviolet ray; and
a chamber for housing the supporting stage, the pressing device and the ultraviolet irradiation device,
wherein the pressing device comprises an ultraviolet transmitting plate;
the pressing device drives the ultraviolet transmitting plate to generate a pressing force for pressing the semiconductor wafer with the protective member attached thereto on the supporting stage;
the ultraviolet transmitting plate is disposed at a side of the pressing device facing the supporting stage and bears the pressing force from the pressing device;
the pressing device is moved relatively to the supporting stage to make the ultraviolet transmitting plate in contact with a surface of the protective member that is opposite to an attaching surface of the protective member and the semiconductor wafer, such that the semiconductor wafer with the protective member attached thereto is sandwiched between the ultraviolet transmitting plate and the supporting stage, and the ultraviolet ray emitted from the ultraviolet irradiation device passes through the ultraviolet transmitting plate and is irradiated to the protective member.

2. The semiconductor manufacturing apparatus of claim 1, wherein the pressing device and the ultraviolet irradiation device are configured in an in-line way or in a standalone way.

3. The semiconductor manufacturing apparatus of claim 1, wherein the pressing device is configured to press the whole area of a surface of the protective member simultaneously, and the surface of the protective member is opposite to the attaching surface of the protective member and the semiconductor wafer.

4. The semiconductor manufacturing apparatus of claim 1, wherein the ultraviolet transmitting plate is a flat plate with ultraviolet transmitting property.

5. The semiconductor manufacturing apparatus of claim 1, further comprising a wafer loader, a wafer unloader, a transporting portion, a rear surface grinding portion, an alignment portion, a laminating portion or a cleaning portion.

6. A semiconductor manufacturing method, comprising:
a preparing step for preparing a semiconductor wafer having a first main surface and a second main surface and a protective member having a first main surface and a second main surface;
a laminating step for attaching the first main surface of the semiconductor wafer to the first main surface of the protective member;
a pressing step for pressing the protective member attached to the semiconductor wafer by regarding the second main surface of the protective member as a pressing surface; and
a hardening step for hardening the protective member attached to the semiconductor wafer by irradiating an ultraviolet ray under the condition that the second main surface of the protective member is being pressed,
wherein a thickness of the protective member is substantially uniform by the pressing step, and the thickness in a substantially uniform of the protective member is maintained by the hardening step.

7. The semiconductor manufacturing method of claim 6, wherein a total thickness variation of the protective member is equal to or less than 1 micrometer through the pressing step.

8. The semiconductor manufacturing method of claim 6, wherein the pressing step is performed by pressing the whole area of the second main surface of the protective member simultaneously by an ultraviolet transmitting plate.

9. The semiconductor manufacturing method of claim 6, wherein the pressing step and the hardening step are performed in an in-line way or in a standalone way.

10. The semiconductor manufacturing method of claim 6, further comprising a rear surface grinding step, an alignment step, a peeling step or a cleaning step.

11. A method for manufacturing a semiconductor device, comprising:
preparing a semiconductor wafer including a first surface, a second surface opposite to the first surface, and a plurality of semiconductor chips formed on the first surface;
preparing a protective member including an adhesive layer that is ultraviolet curable;
laminating the protective member on the first surface of the semiconductor wafer so that the adhesive layer faces the semiconductor wafer;
pressing the semiconductor wafer via the protective member by a pressing plate, the pressing plate having permeability for an ultraviolet ray; and
irradiating the ultraviolet ray to the adhesive layer of the protective member while keeping the semiconductor wafer via the protective member being pressed by the pressing plate for curing the adhesive layer,
wherein the pressing the semiconductor wafer and the irradiating the ultraviolet ray are performed in a chamber.

12. The method for manufacturing the semiconductor device of claim 11, further comprising:
grinding the second surface of the semiconductor wafer while keeping the protective member being laminated on the semiconductor wafer after the irradiating the ultraviolet ray.

13. The method for manufacturing the semiconductor device of claim 11, wherein a thickness of the protective member is substantially uniform by the pressing the semiconductor wafer, and the substantially uniform thickness of the adhesive layer is maintained by the curing the adhesive layer.
